(19) United States
(12) Patent Application Publication
(10) Pub. No.: US 2010/0019803 A1
(43) Pub. Date: Jan. 28, 2010

(54) OSCILLATION DETECTION CIRCUIT

(76) Inventors: Koichi FUKUSHIMA, Tochigi (JP); Eiichi Hasegawa, Tochigi (JP)

Correspondence Address: WENDEROTH, LIND & PONACK, L.L.P., 1030 15th Street, N.W.,, Suite 400 East, Washington, DC, 20005-1503, US

(21) Appl. No.: 12/502,417

(22) Filed: Jul. 14, 2009

(30) Foreign Application Priority Data
Jul. 22, 2008 (JP) 2008-188092

(51) Int. Cl. G01R 19/00

(52) U.S. Cl. 327/18

(57) ABSTRACT

An oscillation detection circuit according to the present invention has a differential circuit by a bipolar transistor where oscillation output of an oscillation circuit is inputted; a capacitance element that is connected to an output terminal of this differential circuit and charges or discharges in response to potential of the output terminal; and a detection circuit that detects a desired oscillation state of an oscillation signal terminal based on potential of this capacitance element.

### BACKGROUND OF THE INVENTION

The present invention relates to an oscillation detection circuit for detecting that amplitude of oscillation output becomes larger than desired amplitude in an oscillation circuit.

Conventionally, an oscillation detection circuit disclosed by Japanese Patent No. 3564976 is known for detecting an oscillation state of an oscillation circuit in the oscillation circuit using a piezoelectric oscillator that is connected between input and output of an invert amplifier circuit configured by a CMOS inverter or the like. The oscillation detection circuit described in the Patent Publication comprises a differential amplifier that is configured by a CMOS circuit having a first input terminal for inputting a reference voltage and a second input terminal for inputting an oscillation output; a current restriction means for restricting a current passing through the differential amplifier; and a control circuit for controlling charge or discharge of a capacitance element in response to an output of the differential amplifier. Therefore, the oscillation detection circuit detects a desired state of the oscillation output based on a potential of the capacitance element.

However, it is difficult to say that the oscillation detection circuit described in the Patent Publication is the most preferred configuration in the oscillation circuit that requires oscillation output of high frequency because the oscillation detection circuit is completely configured by CMOS circuit. In other words, although IC for crystal oscillation has been developed with the CMOS circuit in order to meet the demand of compactness of a chip size and a low consumption current, the electric power passed into crystal used as a piezoelectric oscillator (crystal electric power) has become restricted as the oscillation frequency becomes high. Then, to cope with this, improvement such as an Rd (output resistance)-built-in oscillation circuit is attempted in CMOS (for example, Japanese Patent No. 2535802). Further, to meet the demand for further lower electric power in a future oscillation circuit, it is necessary to employ a circuit using a bipolar transistor. The bipolar oscillation circuit is structurally characterized by difficulty in electric power passage.

Further, the circuit developed by present inventors is conventionally known as an oscillation detection circuit using the bipolar transistor and a configuration thereof is shown in FIG. 8. The oscillation detection circuit comprises a resistance 3 and a resistance 4 that are connected in series between a power supply and an earth ground for biasing a base of NPN bipolar transistor 6 to a desired potential; a resistance 5 for biasing a collector of the NPN bipolar transistor 6 to a desired potential; a capacitance element 7 connected to the collector of the NPN bipolar transistor 6 for charge and discharge; and a CMOS inverter 8 for detecting a state of a desired oscillation output based on the potential of the capacitance element 7.

According to such the configuration, in an ideal action, in a case where amplitude (voltage value) of the oscillation output at the time of oscillation start is smaller than a preset desired value, a base potential of the NPN bipolar transistor 6 does not reach a state that a collector electric current flows. Subsequently, in a case where the amplitude becomes larger than the desired value, the collector electric current of the NPN bipolar transistor 6 flows so that the capacitance element 7 is discharged, output of the CMOS inverter 8 is inverted, and a signal (Vout) detecting the amplitude is outputted.

However, even though the bipolar transistor is used, there exist problems described below in the circuit shown in FIG. 8. In other words, a malfunction may be caused by a leakage current of the NPN bipolar transistor 6 itself in the oscillation detection circuit as a whole.

More specifically, in a case where amplitude of the oscillation output is smaller than the desired value when no leakage current exists in the NPN bipolar transistor 6 itself, the NPN bipolar transistor 6 is turned off, and the capacitance element 7 maintains a specific potential determined based on a portion of voltage drop of the resistor 5. On the contrary, when a leakage current exists, the capacitance element 7 is gradually discharged through the NPN bipolar transistor 6 and potential thereof is unintentionally lowered. Then, due to decrease in potential of this capacitance element 7, output of the CMOS inverter 8 is inverted before amplitude of the oscillation output becomes larger than the desired value, and a signal detecting oscillation is caused to output.

The present invention is made to solve these problems, and it is an object of the present invention to provide an oscillation detection circuit for detecting that amplitude of an oscillation output becomes larger than a desired one, where it is possible to use a bipolar transistor to meet a demand for further lower electric power, so that occurrence of malfunction caused by a leakage current is eliminated.

### SUMMARY OF THE INVENTION

In order to achieve the object, an oscillation detection circuit according to the present invention comprises an oscillation circuit that is connected to a crystal oscillator and outputs an oscillation signal;

a differential circuit that is configured by a plurality of bipolar transistors, has a first input terminal connected to a reference voltage source and a second input terminal connected to an output terminal of the oscillation circuit, and outputs voltage based on a comparison result of potential between the both terminals;

a capacitance element that is connected to an output terminal of the differential circuit and charges or discharges in response to the potential of the output terminal; and

a detection circuit that detects that the oscillation signal is in a desired state, for example, amplitude of the oscillation signal reaches a desired value, based on potential of the capacitance element.

As a more specific configuration of the oscillation detection circuit according to the present invention, there are following configurations.

The second input terminal in the differential circuit is biased to lower voltage than a reference voltage inputted into the first input terminal and output potential of the differential circuit is high level, when there is no oscillation signal from the oscillation circuit and in an oscillation initial state.

Further, the second input terminal in the differential circuit is biased to higher voltage than the reference voltage inputted into the first input terminal and output potential of the differential circuit is low level, when there is no oscillation signal from the oscillation circuit and in an oscillation initial state.

Further, the differential circuit has a differential unit that generates output potential based on a comparison result of potential between the first terminal and the second terminal; and an inverting unit that comprises a bipolar transistor and a resistance element, which are connected in series between power supplies, and generates invert potential of the differential unit output.

Further the detection circuit is configured by a Schmitt circuit.

### BRIEF DESCRIPTION OF THE DRAWINGS

FIG. 1 is a circuit diagram showing an oscillation detection circuit according to a first embodiment of the present invention.

FIG. 2 is a waveform diagram showing a voltage change in respective nodes of the oscillation detection circuit shown in FIG. 1.

FIG. 3 is a circuit diagram showing a configuration of the oscillation circuit shown in FIG. 1.

FIG. 4 is a circuit diagram showing an oscillation detection circuit according to a second embodiment of the present invention.

FIG. 5 is a waveform diagram showing a voltage change in respective nodes of the oscillation detection circuit shown in FIG. 4.

FIG. 6 is a circuit diagram showing an oscillation detection circuit according to a third embodiment of the present invention.

FIG. 7 is a waveform diagram showing a voltage change in respective nodes of the oscillation detection circuit shown in FIG. 6.

FIG. 8 is a circuit diagram showing an oscillation detection circuit according to a conventional art.

### DESCRIPTION OF THE PREFERRED EMBODIMENTS

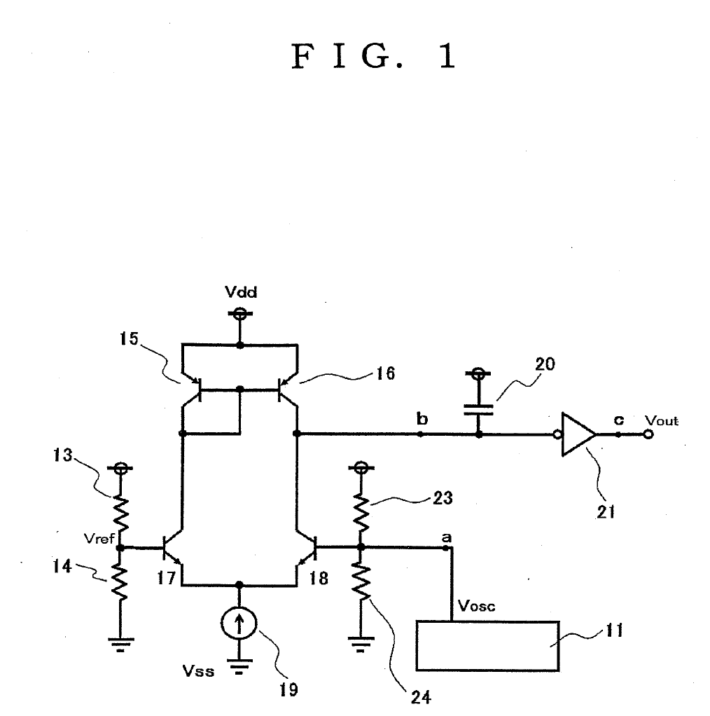

Hereinafter, a first preferred embodiment according to the present invention is described with reference to FIGS. 1 to 3.

An oscillation detection circuit comprises a differential circuit where oscillation output (Vosc) of an oscillation circuit 11 is inputted, this input and a reference voltage are compared, and voltage is outputted based on a result of the comparison; a capacitance element 20 charging or discharging according to the output of the differential circuit; and a detection circuit 21 detecting a desired oscillation state based on potential change of the capacitance element 20 and outputting the result as Vout.

Specifically the differential circuit has a PNP bipolar transistor 15 and an NPN bipolar transistor 17 that are connected in series in a current passage between a high-potential-side power supply Vdd and a low-potential-side power supply Vss, and has a PNP bipolar transistor 16 and an NPN bipolar transistor 18 that are connected in series in a current passage between the power supplies as well. Both emitters of the NPN bipolar transistor 17 and the NPN bipolar transistor 18 are commonly connected and connected to a constant current source 19. Further, both bases of the PNP bipolar transistor 15 and the PNP bipolar transistor 16 are commonly connected and a common connection point is connected to a collector of the PNP bipolar transistor 15.

The reference voltage (Vref) generated by resistance elements 13 and 14 that are connected in series between power supplies is inputted into the base of the NPN bipolar transistor 17. An oscillation output voltage (Vosc) of the oscillation circuit 11 is inputted into the base of the NPN bipolar transistor 18. Further, when there is no oscillation signal from the oscillation circuit 11, the base of the NPN bipolar transistor 18 is biased to a lower voltage than the reference voltage (Vref) by a voltage-division ratio of a resistance element 23 and a resistance element 24. Therefore, differential due to the both input voltages applied to the base of the transistors 17 and 18 is formed.

Output of the differential circuit is taken out from a collector side of the NPN bipolar transistor 18, and the capacitance element 20 is charged or discharged in response to the output voltage thereof. The detection circuit 21 detects a desired oscillation state based on a potential change (result of discharge) of the capacitance element 20. The detection circuit 21 is configured by, for example, a CMOS inverter.

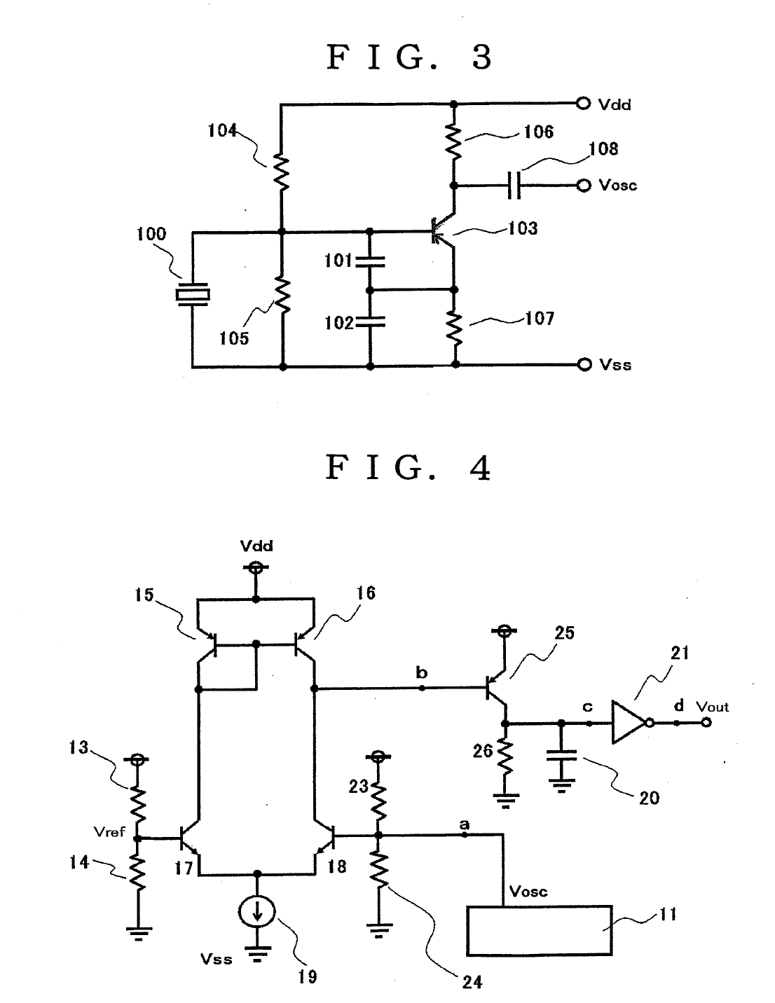

Next, a configuration of the oscillation circuit 11 shown in FIG. 1 is described using a circuit diagram of FIG. 3. The configuration shown in the figure is an example of a typical Colpitts-type oscillation circuit, and various modifications are added by usage. The oscillation circuit has an oscillation bipolar transistor 103 where a collector is connected to the high-potential-side power supply (Vdd) through a load resistance 106, and an emitter is connected to a low-potential-side power supply (Vss) through a resistance element 107; a crystal oscillator 100 connected between a base thereof and the low-potential-side power supply (Vss); and resistance elements 104 and 105 that are connected in series for providing bias to the base of the oscillation bipolar transistor 103. Further signals of both ends of the crystal oscillator 100 are voltage-divided by capacitance elements 101 and 102 that are connected in series, and the connection point thereof is connected to the emitter of the bipolar transistor 103.

Then the oscillation signal outputted from a collector side of the oscillation bipolar transistor 103 is provided through a capacitance element 108 to a next-stage circuit (oscillation detection circuit shown in FIG. 1) as an oscillation output (Vosc). In this oscillation circuit, although the oscillation output is taken out through the capacitance element 108, this capacitance element 108 may be excluded if bias of the oscillation output is stable.

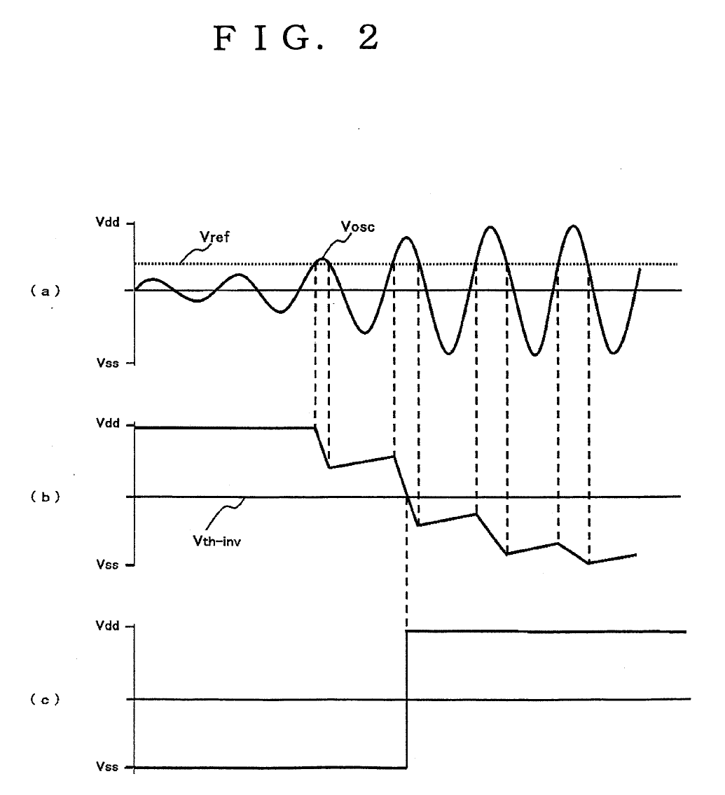

Next, an action of the oscillation detection circuit according to the first embodiment described above is described with reference to FIG. 2. FIG. 2 is a waveform diagram showing voltage change of respective nodes, and (a) (b) and (c) show state of node a, node b, and node c respectively.

When oscillation starts in the oscillation circuit 11, amplitude (voltage level) of an oscillation waveform of the node a (=Vout) gradually increases. When the amplitude exceeds a threshold value (Vref) setup at a reference voltage by a lapse of predetermined time, the NPN bipolar transistor 18 turns on to decrease a potential of the node b (ref. to FIG. 2(b)). In other words, potential of the capacitance element 20 that is in a state of charge because one end is connected to a power supply is discharged by passage of a collector current to the NPN bipolar transistor 18.

When a holding potential of the capacitance element 20 reaches a level of invert threshold value (Vth-inv) of the detection circuit 21 (CMOS inverter), output (Vout) of the detection circuit that is in a level of earth ground (Vss) changes to a level of power supply voltage (Vdd) (ref. to FIG. 2(c)). Accordingly, the oscillation state is detected.

Thus, by employing the oscillation detection circuit using the differential circuit due to the bipolar transistor, it is possible to restrict occurrence of a leakage current in the configuration of the circuit of lowered electric power, and it is enabled to prevent erroneous detection caused by timing when the oscillation signal terminal does not reach a desired oscillation state.

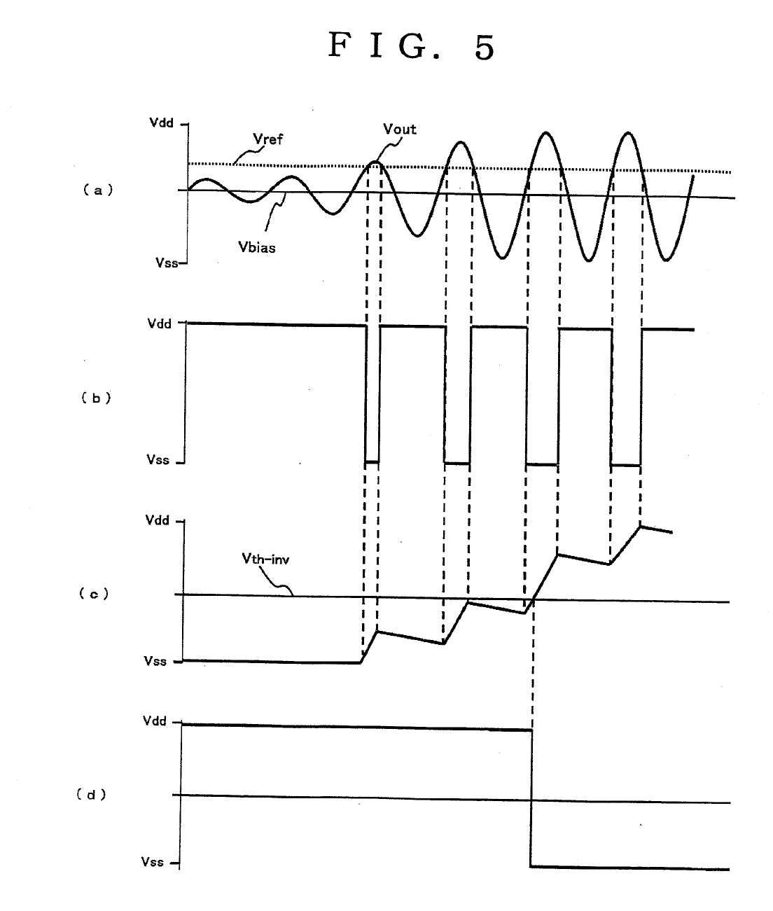

Next, a second embodiment according to the present invention is described with reference to FIGS. 4 and 5. Same reference numbers in the circuit diagram of FIG. 4 are put to elements corresponding to those of the first embodiment described before.

An oscillation detection circuit comprises a differential circuit where oscillation output (Vosc) of an oscillation circuit 11 is inputted, this input is compared with a reference voltage (Vref), and voltage is outputted based on the result; a capacitance element 20 that charges or discharges in response to output of the differential circuit; and a detection circuit 21 where a desired oscillation state is detected based on potential change of the capacitance element 20 and the result is outputted as Vout.

The differential circuit comprises a differential unit and an inverting unit. The differential unit has a PNP bipolar transistor 15 and an NPN bipolar transistor 17 that are connected in series in current passage between a high-potential-side power supply Vdd and a low-potential-side power supply Vss, and has a PNP bipolar transistor 16 and an NPN bipolar transistor 18 that are connected in series in a current passage between power supplies as well. Both emitters of the NPN bipolar transistor 17 and the NPN bipolar transistor 18 are commonly connected and connected to a constant current source 19. Further both bases of the PNP bipolar transistor 15 and the PNP bipolar transistor 16 are commonly connected, and the common connection point is connected to a collector of the PNP bipolar transistor 15.

The reference voltage (Vref) generated by resistance elements 13 and 14 that are connected in series between power supplies is inputted into a base of the NPN bipolar transistor 17. An oscillation output voltage (Vosc) of the oscillation circuit 11 is inputted into a base of the NPN bipolar transistor 18. Further, when there is no oscillation signal from the oscillation circuit, the base of the NPN bipolar transistor 18 is biased to lower voltage than the reference voltage by a voltage-division ratio of a resistance element 23 and a resistance element 24. Accordingly differential is formed by both input voltages applied to the base of the transistors 17 and 18, and output of the differential unit is taken out from the collector side of the NPN bipolar transistor 18.

The inverting unit comprises a PNP bipolar transistor 25 and a resistance element 26 that are connected in series in the current passage between the high-potential-side power supply Vdd and the low-potential-side power supply Vss. An output terminal (collector of the NPN bipolar transistor 18) of the differential unit is connected to the base of the PNP bipolar transistor 25, and a potential of the collector is an output for controlling charge/discharge of the capacitance element 20 at later stage.

The capacitance element 20 charges or discharges in response to a collector potential of PNP bipolar transistor 25, and the detection circuit 21 detects a desired oscillation state based on a potential change (charge result) of the capacitance element 20. The detection circuit 21 is configured by, for example, a CMOS inverter.

In FIG. 4, since a configuration of the oscillation circuit 11 shown in the block is same as in FIG. 3, similar to the first embodiment, description is omitted.

Next, an action of the oscillation detection circuit according to the second embodiment is described with reference to FIG. 5. FIG. 5 is a waveform diagram showing voltage change of respective nodes, and (a), (b), (c), and (d) show a state of nodes a, b, c, and d respectively.

When oscillation starts in the oscillation circuit 11, amplitude (voltage level) of the oscillation waveform of the node a (=Vout) gradually increases. When the amplitude exceeds a threshold value (Vref) setup at the reference voltage by lapse of predetermined time, the NPN bipolar transistor 18 turns on to decrease the potential of the node b (ref. to FIG. 5(b)). In other words, potential of the node b that is connected to high potential (Vdd) through the PNP bipolar transistor 16 is shifted to low potential side (Vss) by passage of the collector current to the NPN bipolar transistor 18. Accordingly, the PNP bipolar transistor 25 being previously in an off-state turns on to increase potential of the node c (ref. to FIG. 5(c)). The potential of the capacitance element 20 being previously in a state of discharge because the detection end is connected to low-potential-side power supply (Vss) through the resistance element 26 charges by a passage of the collector current into the PNP bipolar transistor 25.

When the holding potential of the capacitance element 20 reaches a level of invert threshold value (Vth-inv) of the detection circuit 21 (CMOS inverter), output (Vout) of the detection circuit being previously high level (Vdd) is changed to low level (Vss) (ref. to FIG. 5(d)). Accordingly, an oscillation state is detected.

Thus, since the oscillation detection circuit using the differential circuit due to the bipolar transistor is employed, it is possible to restrict occurrence of the leak current in the circuit configuration of lowered electric power. Therefore, it is possible to prevent erroneous detection at the time when the oscillation signal terminal does not reach a desired oscillation state. Further, because a time constant of charge/discharge of the capacitance element 20 is determined based on Gm of the PNP bipolar transistor 25, and abase potential thereof is determined based on not the oscillation output but the output of the differential circuit, design flexibility improves.

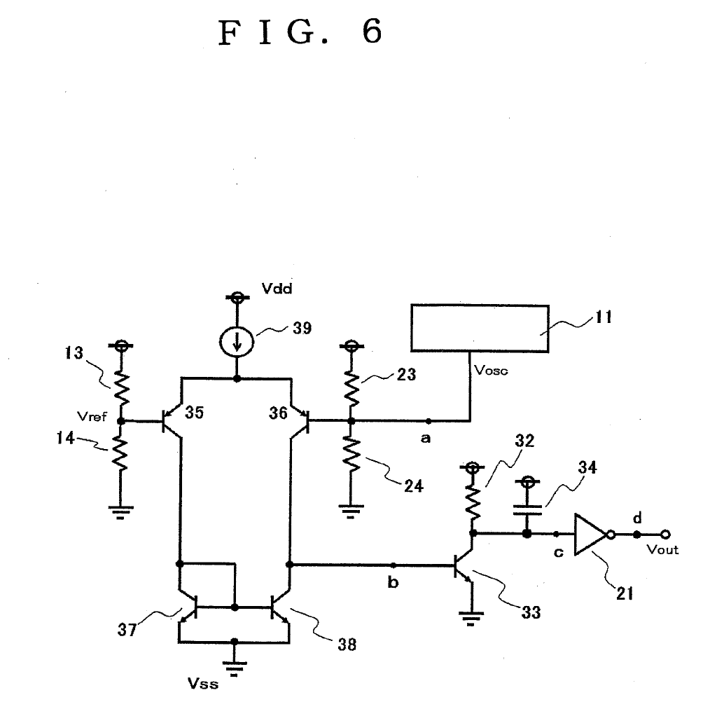

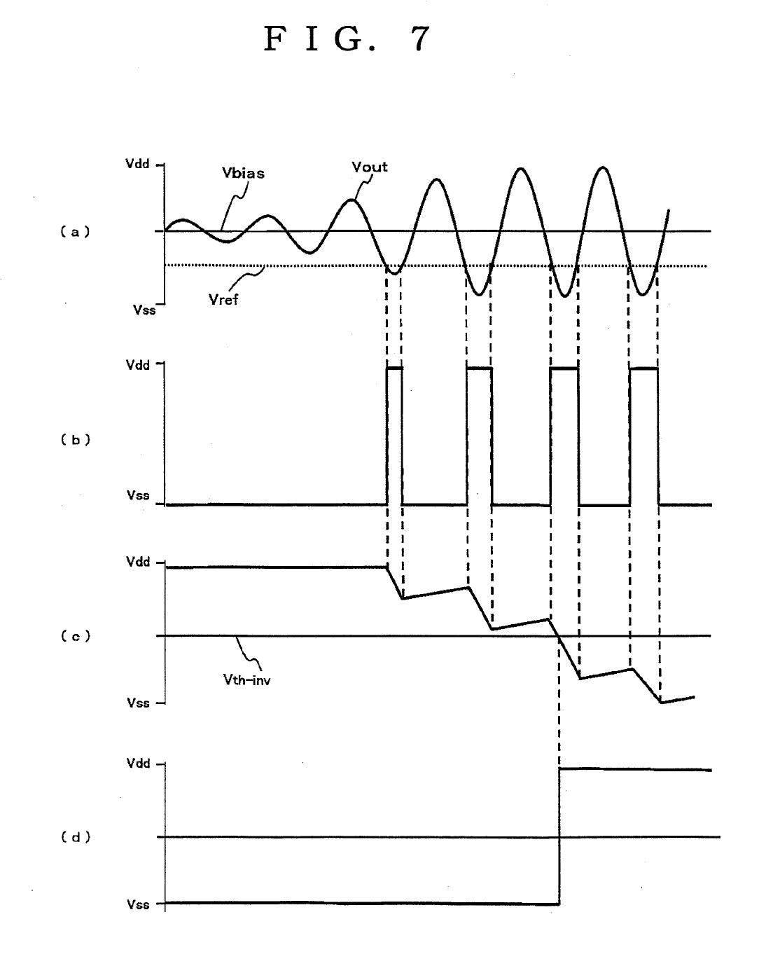

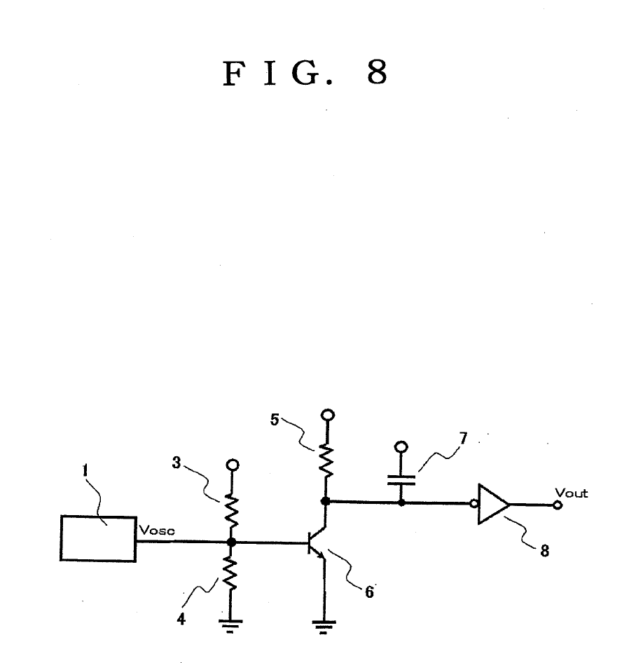

Next, a third embodiment according to the present invention is described with reference to FIGS. 6 and 7. Same reference numbers put in the circuit diagram of FIG. 6 are put to elements corresponding to those of the first and the second embodiments described before.

An oscillation detection circuit comprises a differential circuit where an oscillation output (Vosc) of an oscillation circuit 11 is inputted, this input is compared with a reference voltage, and voltage is outputted based on the result; a capacitance element 34 that charges or discharges in response to output of the differential circuit; and a detection circuit 21 where a desired oscillation state is detected based on potential change of the capacitance element 34 and the result is outputted as Vout.

The differential circuit comprises a differential unit and an inverting unit. The differential unit has a PNP bipolar transistor 35 and an NPN bipolar transistor 37 that are connected in series in current passage between a high-potential-side power supply Vdd and a low-potential-side power supply Vss, and has a PNP bipolar transistor 36 and an NPN bipolar transistor 38 that are connected in series in a current passage between power supplies as well. Both emitters of the PNP bipolar transistor 35 and the PNP bipolar transistor 36 are commonly connected and connected to a constant current source 39. Further both bases of the NPN bipolar transistor 37 and the NPN bipolar transistor 38 are commonly connected, and the common connection point is connected to a collector of the NPN bipolar transistor 37.

The reference voltage (Vref) generated by resistance elements 13 and 14 that are connected in series between power supplies is inputted into the base of the PNP bipolar transistor 35. An oscillation output voltage (Vosc) of the oscillation circuit 11 is inputted into the base of the PNP bipolar transistor 36. Further, when there is no oscillation signal from the oscillation circuit 11, the base of the PNP bipolar transistor 36 is biased to higher voltage than the reference voltage by a voltage-division ratio of a resistance element 23 and a resistance element 24. Accordingly differential is formed by both input voltages applied to the base of the transistors 35 and 36, and output of the differential unit is taken out from the collector side of the PNP bipolar transistor 36.

The inverting unit comprises a resistance element 32 and an NPN bipolar transistor 33 that are connected in series in the current passage between the high-potential-side power supply Vdd and the low-potential-side power supply Vss. An output terminal (collector of the NPN bipolar transistor 36) of the differential unit is connected to the base of the NPN bipolar transistor 33, and potential of the collector is an output for controlling charge/discharge of the capacitance element 34 at later stage.

The capacitance element 34 charges or discharges in response to output of the NPN bipolar transistor 33 and the detection circuit 21 detects a desired oscillation state based on a potential change (discharge result) of the capacitance element 34. The detection circuit 21 is configured by, for example, a CMOS inverter.

In FIG. 6, since a configuration of the oscillation circuit 11 shown in the block is same as in FIG. 3, similar to the first embodiment, description is omitted.

Next, an action of the oscillation detection circuit according to the third embodiment is described with reference to FIG. 7. FIG. 7 is a waveform diagram showing voltage change of respective nodes, and (a), (b), (c), and (d) show a state of nodes a, b, c, and d respectively.

When oscillation starts in the oscillation circuit 11, amplitude (voltage level change) of oscillation waveform of the node a (=Vout) gradually increases. When the amplitude of the low potential side falls below a threshold value (Vref) setup at the reference voltage by lapse of predetermined time, the PNP bipolar transistor 36 turns on to increase potential of the node b (ref. to FIG. 7(b)). In other words, potential of the node b that is connected to the low-potential-side power supply (Vss) through the NPN bipolar transistor 38 is shifted to high potential side (Vdd) by passage of the collector current to the PNP bipolar transistor 36. Accordingly, the NPN bipolar transistor 33 being previously in an off-state turns on to decrease potential of the node c (ref. to FIG. 7(c)). In other words, potential of the capacitance element 34 being previously in a state of charge because a detection end is connected to high-potential-side power supply (Vdd) through the resistance element 32 is discharged by a passage of the collector current to the NPN bipolar transistor 33.

When a holding potential of the capacitance element 34 reaches a level of invert threshold value (Vth-inv) of the detection circuit 21 (CMOS inverter), output (Vout) of the detection circuit being previously low level (Vss) changes to high level (Vdd) (ref. to FIG. 7(d)). Accordingly, an oscillation state is detected.

Thus, since the oscillation detection circuit using the differential circuit due to the bipolar transistor is employed, it is possible to restrict occurrence of the leak current in the circuit configuration of lowered electric power. Therefore it is possible to prevent erroneous detection at the time when the oscillation signal terminal does not reach a desired oscillation state. Further, because a time constant of charge/discharge of the capacitance element 34 is determined based on Gm of the NPN bipolar transistor 33 and a base potential thereof is determined based on not the oscillation output but the output of the differential circuit, design flexibility improves.

In the above-described embodiments from the first to the third, it is described that the detection circuit 21 for finally detecting an oscillation state is configured by the CMOS inverter. However the present invention is not restricted by this. In other words, the detection circuit 21 may be configured by a Schmitt circuit.

In the detection circuit 21, although output is inverted by detecting that potential of the capacitance elements 20 and 34 at the previous stage reaches a desired value, potential of the capacitance element is unstable at an oscillation initial state. When unstable state is repeated around the above-described desired value, output of the detection circuit 21 also becomes unstable following the potential. In the detection circuit 21 configured by the Schmitt circuit, once-inverted output of the detection circuit 21 does not follow a subsequent minute potential change of the capacitance element due to hysteresis characteristics, but maintains an inverted output. Therefore, it is possible to obtain a stable detection result.

According to the oscillation detection circuit of the present invention, it is possible to restrict the potential change of the capacitance element in a small amplitude time at the start of oscillation. Accordingly, it is possible to prevent erroneous detection at the timing when the oscillation signal terminal does not reach a desired oscillation state.

1. An oscillation detection circuit comprising:
an oscillation circuit that is connected to a crystal oscillator provided outside and outputs an oscillation signal;
a differential circuit that is configured by a plurality of bipolar transistors, has a first input terminal connected to a reference voltage source and a second input terminal connected to an output terminal of the oscillation circuit, and has output based on a comparison result of potential between the both terminals;
a capacitance element that is connected to an output terminal of the differential circuit and charges or discharges in response to the potential thereof; and
a detection circuit that detects that the oscillation signal is in a desired state based on potential of the capacitance element.

2. The oscillation detection circuit according to claim 1,
wherein the second input terminal in the differential circuit is biased to lower voltage than a reference voltage inputted into the first input terminal and output potential of the differential circuit is high level, when there is no oscillation signal from the oscillation circuit and in an oscillation initial state.

3. The oscillation detection circuit according to claim 1,
wherein the second input terminal in the differential circuit is biased to higher voltage than the reference voltage inputted into the first input terminal and the output potential of the differential circuit is low level, when there is no oscillation signal from the oscillation circuit and in the oscillation initial state.

4. The oscillation detection circuit according to claim 2,
wherein the differential circuit has a differential unit that generates output potential based on a comparison result of potential between the first terminal and the second terminal; and an inverting unit that comprises a bipolar transistor and a resistance element, which are connected in series between power supplies, and generates invert potential of output of the differential unit.

5. The oscillation detection circuit according to claim 1,
wherein the detection circuit is configured by a Schmitt circuit.

6. The oscillation detection circuit according to claim 3,
wherein the differential circuit has a differential unit that generates output potential based on a comparison result of potential between the first terminal and the second terminal; and an inverting unit that comprises a bipolar transistor and a resistance element, which are connected in series between power supplies, and generates invert potential of output of the differential unit.
